(19) United States
(12) Patent Application Publication
(10) Pub. No.: US 2025/0336707 A1
(43) Pub. Date: Oct. 30, 2025

(54) ELECTROSTATIC CHUCK AND SUBSTRATE FIXING DEVICE

(71) Applicant: SHINKO ELECTRIC INDUSTRIES CO., LTD., Nagano-shi (JP)

(72) Inventors: Norio Shiraiwa, Nagano (JP); Keita Uruga, Nagano (JP); Hiroyuki Kobayashi, Nagano (JP)

(21) Appl. No.: 19/189,915

(22) Filed: Apr. 25, 2025

(30) Foreign Application Priority Data
Apr. 26, 2024 (JP) 2024-073066

(51) Int. Cl. H01L 21/683; H01J 37/32

(52) U.S. Cl. CPC H01L 21/6833; H01J 37/32715; H01J 2237/2007; H01J 2237/334

(57) ABSTRACT

An electrostatic chuck includes a base body having a placement surface on which a target object to be adsorbed is to be placed; and an electrostatic electrode embedded in the base body, wherein a surface of the base body opposite to the placement surface is a flat surface, and the placement surface is convex or concave with respect to the flat surface.

### CROSS-REFERENCE TO RELATED APPLICATIONS

This application claims priority from Japanese Patent Application No. 2024-073066 filed on Apr. 26, 2024, the contents of which are incorporated herein by reference.

### TECHNICAL FIELD

The present invention relates to an electrostatic chuck and a substrate fixing device.

### BACKGROUND ART

In the related art, a film formation apparatus (for example, a CVD apparatus, a PVD apparatus, and the like) and a plasma etching apparatus, which are used when manufacturing a semiconductor device such as an IC and an LSI, each have a stage for accurately holding a substrate in a vacuum treatment chamber. As such a stage, for example, a substrate fixing device is suggested which adsorbs and holds a substrate, which is a target object to be adsorbed, by an electrostatic chuck mounted on a base plate. For the stage, it is required to stably adsorb any substrate to the electrostatic chuck.

As an example of an electrostatic chuck, an electrostatic chuck may be exemplified which includes an electrostatic chuck body for electrostatically adsorbing a substrate, a support member having a placement surface on which the electrostatic chuck body is placed, a restraint means for restraining displacement of a first portion of the electrostatic chuck body in a direction perpendicular to the placement surface, and a driving means for displacing a second portion of the electrostatic chuck body relative to the placement surface in a direction perpendicular to the placement surface.

### CITATION LIST

### Patent Literature

PTL 1: JP2020-205349A

### SUMMARY OF INVENTION

An object of the present invention is to provide an electrostatic chuck having a simple structure and improved adsorption performance for a target object to be adsorbed with high insulating properties.

According to one aspect of the present disclosure, an electrostatic chuck includes:
a base body having a placement surface on which a target object to be adsorbed is to be placed; and
an electrostatic electrode embedded in the base body, wherein
a surface of the base body opposite to the placement surface is a flat surface, and
the placement surface is convex or concave with respect to the flat surface.

According to the disclosed technology, it is possible to provide an electrostatic chuck having a simple structure and improved adsorption performance for a target object to be adsorbed with high insulating properties.

### BRIEF DESCRIPTION OF DRAWINGS

FIGS. 1A and 1B are simplified views illustrating a substrate fixing device according to a first embodiment.

FIGS. 2A and 2B are partially enlarged cross-sectional views of the substrate fixing device according to the first embodiment.

FIG. 3 is a simplified cross-sectional view illustrating a state in which the substrate fixing device according to the first embodiment adsorbs and holds a sapphire substrate.

FIG. 4 is a simplified cross-sectional view illustrating a state in which a substrate fixing device according to Comparative Example adsorbs and holds a sapphire substrate.

FIG. 5 is a diagram illustrating adsorption characteristics of a substrate fixing device 1X.

FIG. 6 is a diagram illustrating adsorption characteristics of a substrate fixing device 1.

FIGS. 7A and 7B are views illustrating a manufacturing process of a substrate fixing device according to the first embodiment.

FIGS. 8A, 8B, 8C and 8D are views illustrating the manufacturing process of a substrate fixing device according to the first embodiment.

FIGS. 9A and 9B are simplified views illustrating a substrate fixing device according to variation 1 of the first embodiment.

FIGS. 10A and 10B are partially enlarged cross-sectional views of the substrate fixing device according to variation 1 of the first embodiment.

FIG. 11 is a simplified cross-sectional view illustrating a state in which the substrate fixing device according to variation 1 of the first embodiment adsorbs and holds a sapphire substrate.

### DESCRIPTION OF EMBODIMENTS

Hereinafter, embodiments of the present invention will be described with reference to the drawings. Note that, in the respective drawings, the parts having the same configurations are denoted with the same reference signs, and the redundant descriptions may be omitted.

### First Embodiment

### Structure of Substrate Fixing Device

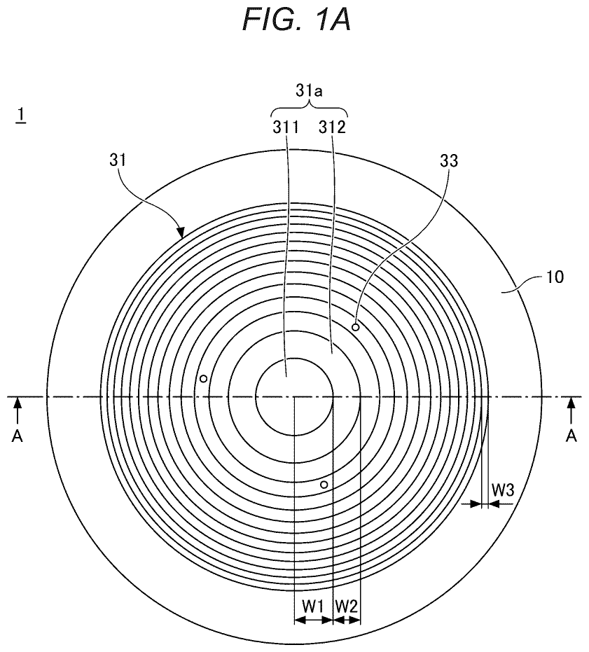

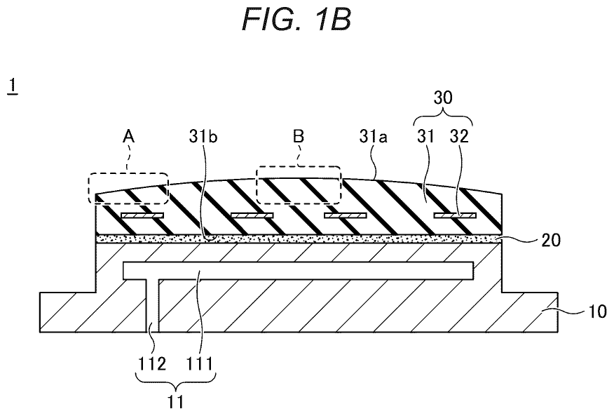

FIGS. 1A and 1B are simplified views illustrating a substrate fixing device according to a first embodiment, in which FIG. 1A is a plan view and FIG. 1B is a cross-sectional view taken along line A-A of FIG. 1A.

Referring to FIGS. 1A and 1B, a substrate fixing device 1 has, main constitutional elements, a base plate 10, an adhesive layer 20, and an electrostatic chuck 30. The substrate fixing device 1 is a device that adsorbs and holds a substrate, which is a target object to be adsorbed, by the electrostatic chuck 30 mounted on one surface of the base plate 10. The target object to be adsorbed is placed, adsorbed, and held on a placement surface 31a of a base body 31 of the electrostatic chuck 30.

The base plate 10 is a member for mounting the electrostatic chuck 30. A thickness of the base plate 10 is, for example, about 20 to 50 mm. The base plate 10 may be formed of, for example, metal such as aluminum, copper, or titanium. Among them, aluminum is preferably used which is inexpensive and easy to process.

The base plate 10 may also be used as an electrode for controlling plasma, or the like. By supplying predetermined high-frequency electric power to the base plate 10, the energy for causing ions and the like in a generated plasma state to collide with the substrate adsorbed on the electrostatic chuck 30 can be controlled to effectively perform etching processing.

A gas supply portion 11 for introducing a gas to cool the substrate adsorbed and held on the electrostatic chuck 30 is provided in the base plate 10. The gas supply portion 11 includes a gas flow channel 111 and a gas injection portion 112.

The gas flow channel 111 is, for example, a hole formed in an annular shape in the base plate 10. The gas injection portion 112 is a hole having one end communicating with the gas flow channel 111 and other end exposed to the outside from a lower surface of the base plate 10, and introduces an inert gas (e.g., He or Ar) into the gas flow channel 111 from the outside of the substrate fixing device 1. The gas flow channel 111 reaches the placement surface 31a of the electrostatic chuck 30 through gas discharge portions 33.

The gas discharge portion 33 is a vertical hole having one end communicating with the gas flow channel 111 and other end exposed to the outside from an upper surface of the base plate 10 and penetrating the adhesive layer 20 and the base body 31, and discharges the inert gas introduced into the gas flow channel 111 to the placement surface 31a. The gas discharge portions 33 are scattered on the placement surface 31a of the base body 31 in plan view. The number of the gas discharge portions 33 is three in the shown example, but the required number can be provided as appropriate, for example, from several tens to several hundreds.

Note that the term ‘plan view’ refers to viewing a target object from the normal direction of the upper surface of the base plate 10, and the term ‘planar shape’ refers to a shape of the target object as viewed from the normal direction of the upper surface of the base plate 10.

A flow channel may be provided inside the base plate 10. In this case, the flow channel is connected to a cooling medium control device provided outside the substrate fixing device 1, and the cooling medium control device introduces and discharges a cooling medium into the flow channel. By circulating the cooling medium through the flow channel using the cooling medium control device to cool the base plate 10, the substrate adsorbed on the electrostatic chuck 30 can be cooled. As the cooling medium, for example, water or Galden may be used.

The electrostatic chuck 30 is mounted on the base plate 10 with the adhesive layer 20 interposed therebetween. As the adhesive layer 20, silicone-based resin may be used, for example. A thickness of the adhesive layer 20 is, for example, about 0.1 to 1.0 mm. The adhesive layer 20 bonds the base plate 10 and the electrostatic chuck 30, and has an effect of reducing stress generated due to a difference in thermal expansion coefficient between the electrostatic chuck 30 made of ceramic and the base plate 10 made of aluminum.

The electrostatic chuck 30 is a part that adsorbs and holds the substrate, which is a target object to be adsorbed. A planar shape of the electrostatic chuck 30 may be circular, for example. A diameter of the substrate, which is a target object to be adsorbed of the electrostatic chuck 30, may be, for example, 6 inches, 8 inches, 12 inches, or 18 inches. The electrostatic chuck 30 is, for example, a Johnson-Rabeck type electrostatic chuck. However, the electrostatic chuck 30 may also be a Coulomb-type electrostatic chuck.

The base body 31 is a dielectric body. As the base body 31, for example, ceramics such as aluminum oxide (Al₂O₃) and aluminum nitride (AlN) may be used. A thickness of the base body 31 may be, for example, about 1 to 10 mm, and a relative permittivity (1 kHz) of the base body 31 may be, for example, about 9 to 10.

An electrostatic electrode 32 is a thin film electrode and is embedded in the base body 31. The electrostatic electrode 32 is connected to a power supply provided outside the substrate fixing device 1, and generates adsorption force between the electrostatic electrode and the substrate by static electricity when a predetermined voltage is applied from the power supply. This enables the substrate to be adsorbed and held on the placement surface 31a of the base body 31 of the electrostatic chuck 30. The higher the voltage applied to the electrostatic electrode 32, the stronger the adsorption holding force is. The electrostatic electrode 32 may have a unipolar shape or a bipolar shape. As a material of the electrostatic electrode 32, tungsten, molybdenum or the like may be used, for example.

The base body 31 may be provided therein with a heating element that generates heat by applying a voltage from the outside of the substrate fixing device 1 and heats the placement surface 31a of the base body 31 to a predetermined temperature. The heating element may be arranged, for example, on a lower side of the electrostatic electrode 32 (on the base plate 10 side).

The target object to be adsorbed of the electrostatic chuck 30 is a silicon substrate or a sapphire substrate. Since the sapphire substrate has high insulating properties, it is more difficult to adsorb and hold the same on the base body 31 compared to the silicon substrate. In particular, when the sapphire substrate is thick and is highly warped, adsorption and holding become difficult. Therefore, in the electrostatic chuck 30, the shape of the placement surface 31a is adapted to match a warpage shape of the sapphire substrate. Note that in the present specification, ‘high insulating properties’ refers to a resistivity of 10¹⁴ Ωcm or higher (25° C.).

In the first embodiment, since a sapphire substrate warped into a convex shape is assumed, the shape of the placement surface 31a is made convex. Specifically, as shown in FIG. 1B, the lower surface of the base body 31 opposite to the placement surface 31a, which is the upper surface, is a flat surface 31b, and the placement surface 31a is convex with respect to the flat surface 31b. The placement surface 31a side of the base body 31 has, for example, a dome shape. That is, a height of the placement surface 31a from the flat surface 31b is highest at the center and decreases toward an outer periphery. However, the base body 31 may have a region where a thickness is partially uniform.

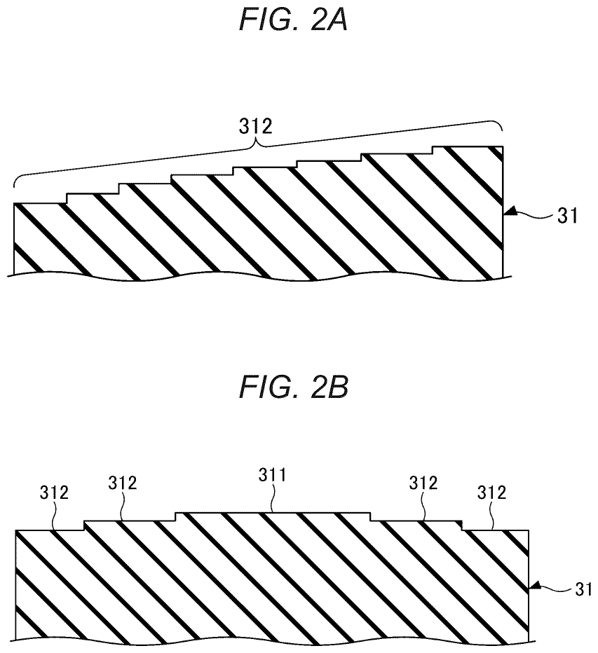

FIG. 2 is a partially enlarged cross-sectional view of the substrate fixing device according to the first embodiment, in which FIG. 2A is an enlarged view of part A of FIG. 1B and FIG. 2B is an enlarged view of part B of FIG. 1B. Note that the magnifications of FIGS. 2A and 2B are the same. As shown in FIGS. 1A, 1B, 2A and 2B, the placement surface 31a may, in plan view, have a circular region 311 located at the center and a plurality of annular regions 312 located at the outer periphery of the circular region 311.

In the example of FIG. 1A, the placement surface 31a has 13 annular regions 312. As shown in FIG. 1A, in plan view, an outer edge of each annular region 312 can be arranged concentrically with respect to the center of the circular region 311, for example. In addition, as shown in FIGS. 2A and 2B, the circular region 311 and each annular region 312 may have a stepped shape in which a height of each step decreases toward the outer periphery in a cross-sectional view.

When the annular regions 312 have a stepped shape, an upper surface of each annular region 312 may be parallel to the upper surface of the base plate 10 or may be inclined with respect to the upper surface of the base plate 10. In addition, the upper surface of each annular region 312 may be a flat surface, a curved surface, or a combination of flat and curved surfaces.

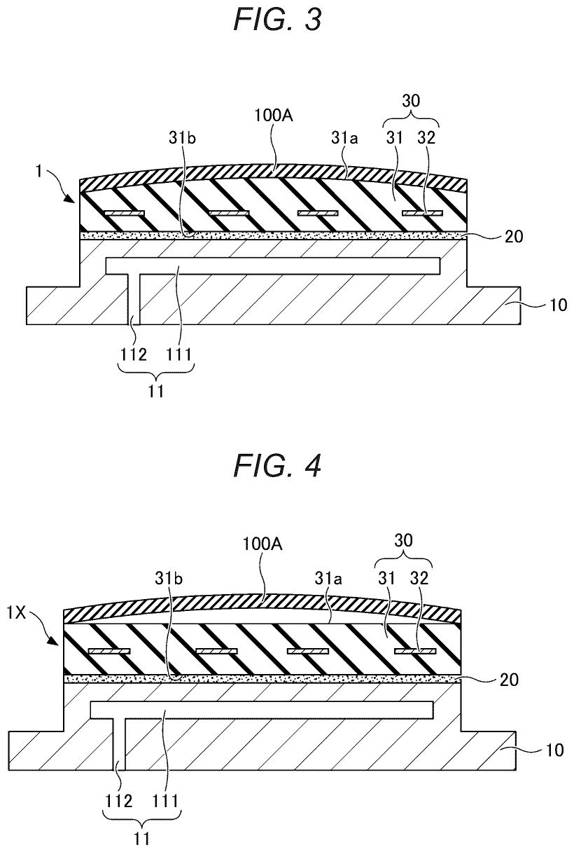

FIG. 3 is a simplified cross-sectional view illustrating a state in which the substrate fixing device according to the first embodiment adsorbs and holds a sapphire substrate. In FIG. 3, a sapphire substrate 100A is warped into a convex shape. The degree of warpage varies depending on the diameter, thickness, manufacturing lot, and the like of the sapphire substrate, but for example, in a sapphire substrate with a diameter of 6 inches and a thickness of 1.5 mm, the warpage may be about 130 μm. That is, in some cases, a difference in height between the center and the outermost periphery may be approximately 130 μm.

When the diameter, thickness, and manufacturing lot of the sapphire substrate 100A to be adsorbed are determined, the tendency of warpage can be determined by extracting samples and measuring the warpage. When the tendency of warpage is determined, the placement surface 31a can be processed to match it, thereby increasing a contact area between the placement surface 31a and the sapphire substrate 100A, as shown in FIG. 3, and enabling favorable adsorption. Below, the adsorption of the sapphire substrate 100A will be described in more detail based on specific data.

FIG. 4 is a simplified cross-sectional view illustrating a state in which a substrate fixing device according to Comparative Example adsorbs and holds a sapphire substrate. In a substrate fixing device 1X according to Comparative Example, a placement surface 31a is a flat surface and is almost parallel to a flat surface 31b, which is the lower surface of the base body 31. That is, the base body 31 has a uniform thickness, so the thickness of the center and the thickness of the outermost periphery are the same. As a result, the contact area between the placement surface 31a and the sapphire substrate 100A is reduced.

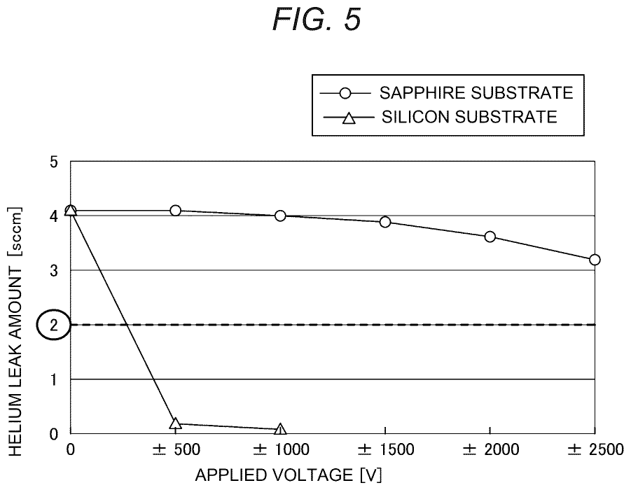

FIG. 5 is a diagram illustrating adsorption characteristics of the substrate fixing device 1X. To measure the adsorption characteristics, a helium leak tester was used. The target object to be measured is a sapphire substrate with a diameter of 6 inches, a thickness of 1.5 mm, and a convex warpage of 130 μm. In addition, as a reference, measurements were conducted on a silicon substrate with a diameter of 6 inches, a thickness of 0.625 mm, and virtually no warpage. The specific measurement method is as follows.

First, the substrate fixing device 1X was attached to the helium leak tester arranged inside the chamber, and the inside of the chamber was evacuated to 20 Pa or less. Then, a sapphire substrate was placed on the placement surface 31a of the substrate fixing device 1X, a voltage was applied to the electrostatic electrode 32 to adsorb the sapphire substrate, and helium gas with a pressure set to 2660 Pa (20 Torr) was supplied to the placement surface 31a via the gas supply portion 11 and the gas discharge portions 33. Then, the leak amount was measured when the numerical value of the helium gas leak amount became constant. This test was conducted while changing the applied voltage to the electrostatic electrode 32, and the results were plotted in FIG. 5. Then, the sapphire substrate was replaced with a silicon substrate, the same measurements were performed, and the results were plotted in FIG. 5. Note that, in FIG. 5, if the leak amount of helium gas is 2 sccm or less, it can be determined that the target object to be measured is sufficiently adsorbed on the placement surface 31a.

As shown in FIG. 5, for the reference silicon substrate, when the applied voltage is ±500 V, the leakage amount of helium gas is 2 sccm or less, and at this point in time, it can be determined that the substrate is sufficiently adsorbed on the placement surface 31a. In contrast, for the sapphire substrate, even when the applied voltage is increased to ±2500 V, the leakage amount of helium gas is 3.2 sccm and does not fall below 2 sccm. That is, even when the applied voltage is increased to ±2500 V, the sapphire substrate is not sufficiently adsorbed on the placement surface 31a. In other words, the substrate fixing device 1X with the flat placement surface 31a cannot adsorb a sapphire substrate with a warpage of 130 μm.

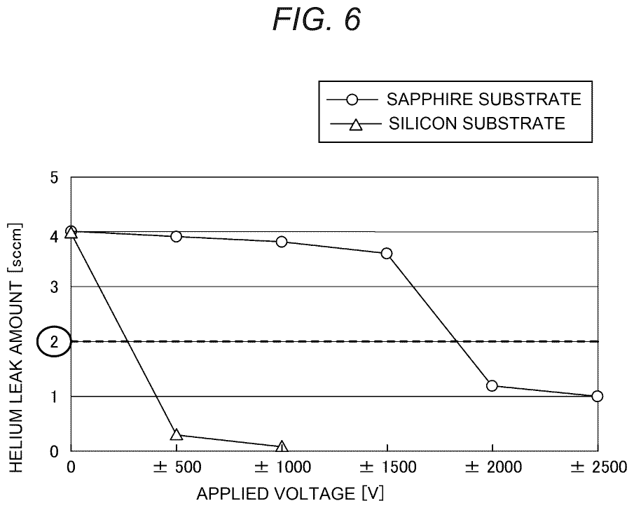

FIG. 6 is a diagram illustrating adsorption characteristics of the substrate fixing device 1. That is, FIG. 6 is a plot of the results obtained by replacing the substrate fixing device 1X with the substrate fixing device 1 and performing the same measurement as above. The specifications of the sapphire substrate and silicon substrate to be adsorbed are also the same as above.

As shown in FIG. 6, similarly to FIG. 5, for the reference silicon substrate, when the applied voltage is ±500 V, the leakage amount of helium gas is 2 sccm or less, and at this point in time, it can be determined that the substrate is sufficiently adsorbed on the placement surface 31a. In contrast, for the sapphire substrate, when the applied voltage was increased to ±2000 V, the leak amount of helium gas was 1.2 sccm, falling to 2 sccm or less. That is, for the substrate fixing device 1, when the applied voltage is increased to ±2000 V, a sapphire substrate with a convex warpage of 130 μm can be sufficiently adsorbed on the convex placement surface 31a.

From the results of FIGS. 5 and 6, it can be concluded that for a sapphire substrate with high insulating properties that is difficult to adsorb, even when the substrate has a significant warpage, sufficient adsorption force can be achieved by adjusting the applied voltage and matching the shape of the placement surface 31a to the warpage shape of the sapphire substrate. Note that it is considered that sufficient adsorption force is achieved by matching the shape of the placement surface 31a to the warpage shape of the sapphire substrate because this increases the contact area between the placement surface 31a and the sapphire substrate.

In addition, if the sapphire substrate is etched without achieving sufficient adsorption, it becomes impossible to uniformly control the in-plane temperature of the sapphire substrate. As a result, the etching process is affected by temperature, leading to a deterioration in etching quality. This problem can be avoided by matching the shape of the placement surface 31a to the warpage shape of the sapphire substrate to achieve sufficient adsorption force. In addition, when the placement surface 31a of the substrate fixing device 1 has a structure with steps like stairs, it is easy to allow helium gas to flow over the entire placement surface 31a.

To increase the contact area between the placement surface 31a and the sapphire substrate, it is necessary to match the shape of the placement surface 31a to the shape of the target object to be adsorbed as closely as possible. In general, the warpage of the target object to be adsorbed is relatively small at the center and increases toward the outer periphery. Therefore, to match the warpage tendency of the target object to be adsorbed, in the embodiment of FIGS. 1A, 1B, 2A and 2B, a radius W1 of the circular region 311 is wider than a width of each annular region 312 in plan view. In addition, in the embodiment of FIGS. 1A, 1B, 2A and 2B, the plurality of annular regions 312 include annular regions 312 with different widths, and the annular region 312 with a greater width is arranged closer to the circular region 311 than the annular region 312 with a smaller width.

When the size of the placement surface 31a is 6 inches, the radius W1 of the circular region 311 can be set to, for example, about 12 mm to 14 mm. Additionally, a width W2 of the annular region 312 closest to the circular region 311 can be set to, for example, about 8.5 mm to 10.5 mm. Additionally, a width W3 of the annular region 312 farthest from the circular region 311 can be set to, for example, about 1.5 mm to 3.5 mm. The widths of some annular regions 312 may be the same.

In addition, when a sapphire substrate with a convex warpage of 130 μm is used as a target object to be adsorbed, and the circular region 311 and the annular regions 312 have a stepped shape, for example, the number of steps can be set to about 13, and the difference in height between adjacent steps can be set to about 10 μm. Thereby, the convex shape of the placement surface 31a can be made to almost match the warpage of the sapphire substrate.

### Manufacturing Method of Substrate Fixing Device

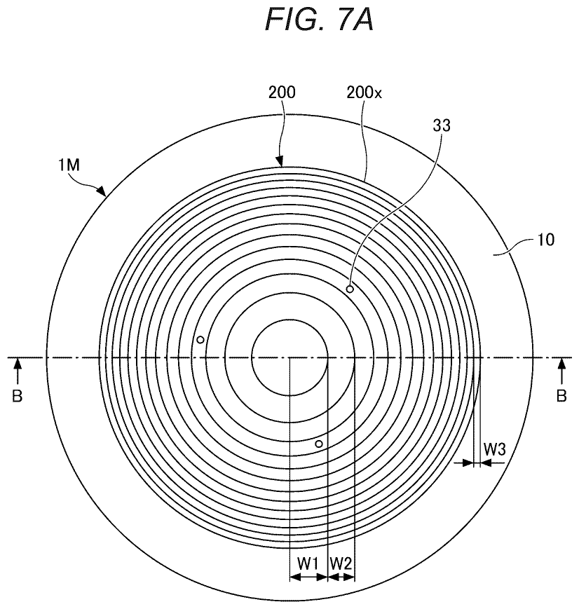

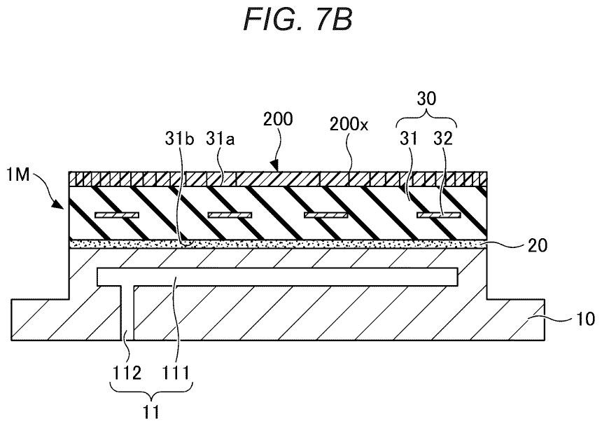

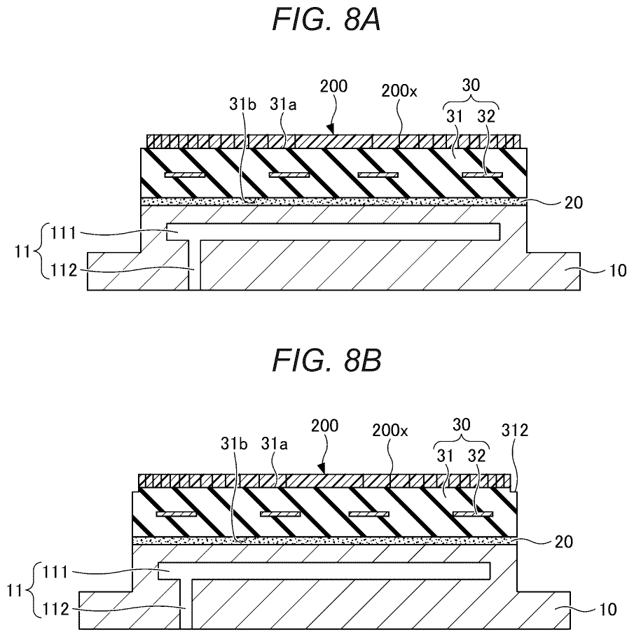

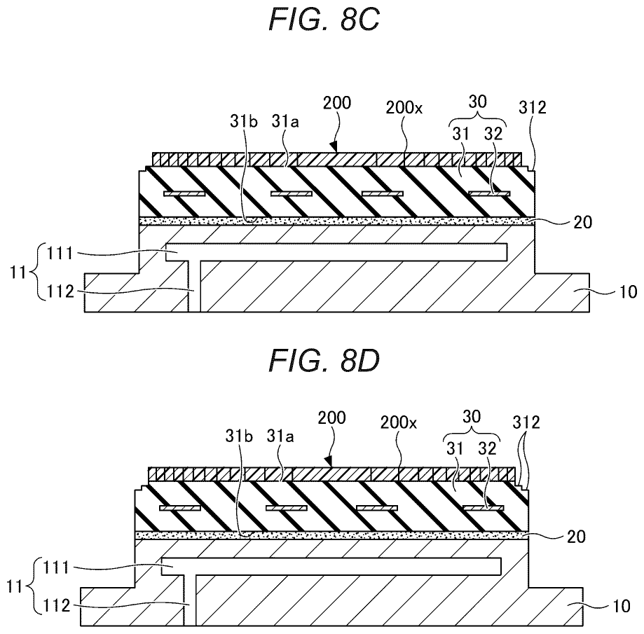

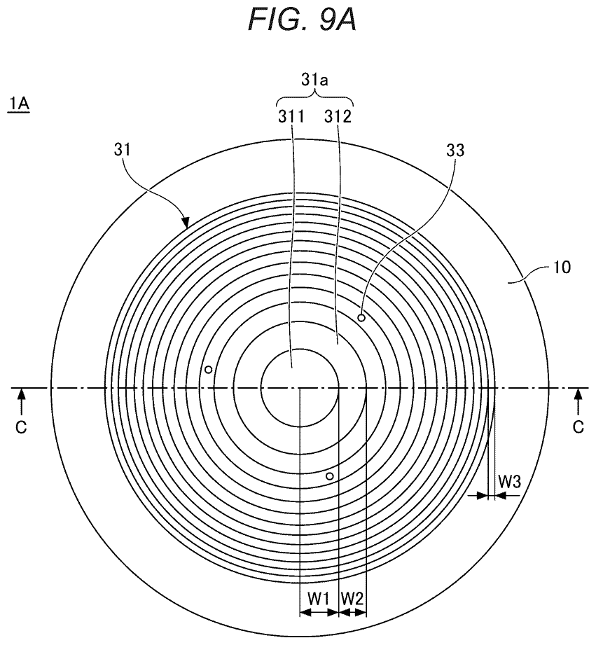

FIGS. 7A and 7B and FIGS. 8A to 8D are views illustrating a manufacturing process of a substrate fixing device according to the first embodiment. Note that FIG. 7A is a plan view, and FIG. 7B is a cross-sectional view taken along line B-B of FIG. 7A. In addition, FIGS. 8A to 8D are cross-sectional views corresponding to FIG. 7B.

First, in the process shown in FIGS. 7A and 7B, an electrostatic chuck 30 having a base body 31 with flat upper and lower surfaces is arranged on a base plate 10 with an adhesive layer 20 interposed therebetween, resulting in fabrication of a substrate fixing device 1M. Then, a mask 200 having a plurality of slits 200x formed concentrically in plan view is arranged so as to cover the entire upper surface of the base body 31.

Specifically, the base body 31 having an electrostatic electrode 32 embedded therein is fabricated by a well-known manufacturing method including, for example, a process of performing via processing on a green sheet, a process of filling vias with a conductive paste, a process of forming a pattern for an electrostatic electrode, a process of stacking and firing other green sheets, a process of flattening a surface, and the like. Then, gas discharge portions 33 are formed to penetrate through the base body 31. The gas discharge portions 33 are formed, for example, by drilling. Then, a base plate 10 having a gas supply portion 11, a cooling mechanism, and the like formed in advance is prepared, and an adhesive layer 20 (uncured) is formed on the base plate 10. Then, the base body 31 is arranged on the base plate 10 with the adhesive layer 20 interposed therebetween, and the adhesive layer 20 is cured. Thereby, the substrate fixing device 1M is completed. Note that the substrate fixing device 1M has the same shape as the substrate fixing device 1, except that the placement surface 31a, which is an upper surface, is a flat surface.

After fabricating the substrate fixing device 1M, the mask 200 is arranged on the placement surface 31a. A planar shape of the mask 200 is a circular shape with the same diameter as the placement surface 31a. That is, at this point in time, the entire placement surface 31a is covered with the mask 200, and no part is exposed. The mask 200 has the plurality of slits 200x formed concentrically in plan view, and each region divided by the slits 200x can be easily peeled along the slits 200x. A spacing between adjacent slits 200x corresponds to the width of one step of the stairs shown in FIG. 2A or FIG. 2B. The mask 200 can be formed of a material such as polyester or Tetron, for example.

Next, in the process shown in FIG. 8A, the outermost periphery region of the mask 200, divided by the slit 200x, is peeled off. That is, the region outside the largest-diameter slit 200x of the mask 200 is peeled off. Thereby, the outermost periphery of the placement surface 31a is exposed in a ring shape.

Next, in the process shown in FIG. 8B, blast processing is performed on the placement surface 31a, which is the upper surface of the base body 31, through the mask 200. Thereby, a first ring-shaped annular region 312 is formed at the outermost periphery of the placement surface 31a. The first annular region 312 is, for example, about 10 μm lower than the placement surface 31a located inside the first annular region 312.

Next, the process of peeling off one division of the mask 200 and the process of performing blast processing are repeated to process the placement surface 31a, which is the upper surface of the base body 31, thereby forming a convex placement surface 31a on which a target object to be adsorbed is placed.

Specifically, as shown in FIG. 8C, the region outside the largest-diameter slit 200x of the mask 200 is peeled off. Thereby, the inner side of the annular region 312 of the placement surface 31a is exposed in a ring shape. Next, as shown in FIG. 8D, blast processing is performed on the placement surface 31a through the mask 200. Thereby, a second ring-shaped annular region 312 is formed inside the outermost periphery annular region 312 of the placement surface 31a. At the same time, the first annular region 312 located at the outermost periphery becomes deeper than the state of FIG. 8C, and the two adjacent annular regions 312 form a step shape. The second annular region 312 is, for example, about 10 μm lower than the placement surface 31a located inside the second annular region 312. In addition, the first annular region 312 is, for example, about 10 μm lower than the second annular region 312.

Thereafter, the processes of peeling off the region outside the largest-diameter slit 200x at that point in time and performing blast processing through the mask 200 are repeated in the same manner until the slit 200x is no longer present. Finally, the circular mask 200 remaining at the center of the placement surface 31a is peeled off. The portion where the circular mask 200 is peeled off becomes a circular region 311.

Thereby, the placement surface 31a has, in plan view, the circular region 311 located at the center and the plurality of annular regions 312 located at the outer periphery of the circular region 311, and in plan view, the outer edge of each of the annular regions 312 is arranged concentrically with respect to the center of the circular region 311. In addition, the circular region 311 and each of the annular regions 312 have a stepped shape in which the height is greatest at the center and decreases toward the outer periphery in a cross-sectional view, resulting in a convex shape as a whole. In plan view, the radius of the circular region 311 may be greater than the width of each annular region 312. In addition, the plurality of annular regions 312 may include annular regions 312 with different widths, and the annular region 312 with a greater width may be arranged closer to the circular region 311 than the annular region 312 with a smaller width.

Note that after completely peeling off the mask 200, polishing using a hand stone or the like may be performed on the edges of each step, thereby forming the entire placement surface 31a into a smooth convex shape. Alternatively, the polishing may be performed partially on the edges of each step, thereby forming the placement surface 31a with curved or chamfered edges of each step.

### Variation 1 of First Embodiment

Variation 1 of the first embodiment shows an example of a substrate fixing device having a placement surface shape different from that of the first embodiment. Note that, in variation 1 of the first embodiment, the descriptions of the same constitutional parts as the embodiment already described may be omitted.

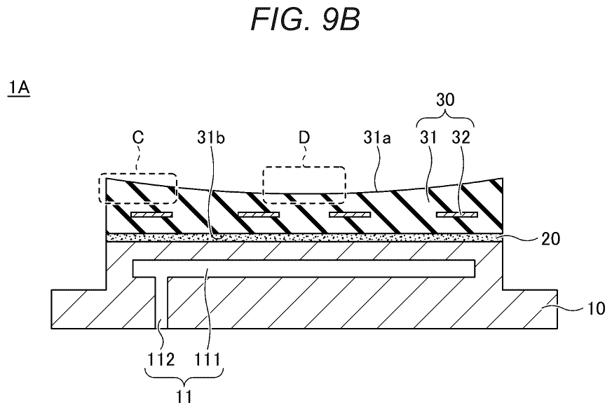

FIG. 9 is a simplified view illustrating a substrate fixing device according to variation 1 of the first embodiment, in which FIG. 9A is a plan view and FIG. 9B is a cross-sectional view taken along line C-C of FIG. 9A. Referring to FIGS. 9A and 9B, a substrate fixing device 1A differs from the substrate fixing device 1 in that the placement surface 31a of the base body 31 is concave with respect to the flat surface 31b.

In variation 1 of the first embodiment, since a sapphire substrate warped into a concave shape is assumed, the shape of the placement surface 31a is made concave. Specifically, as shown in FIG. 9B, the lower surface of the base body 31 opposite to the placement surface 31a, which is the upper surface, is a flat surface 31b, and the placement surface 31a is concave with respect to the flat surface 31b. The placement surface 31a side of the base body 31 has, for example, a bowl shape. That is, a height of the placement surface 31a from the flat surface 31b is lowest at the center and increases toward the outer periphery. However, the base body 31 may have a region where a thickness is partially uniform.

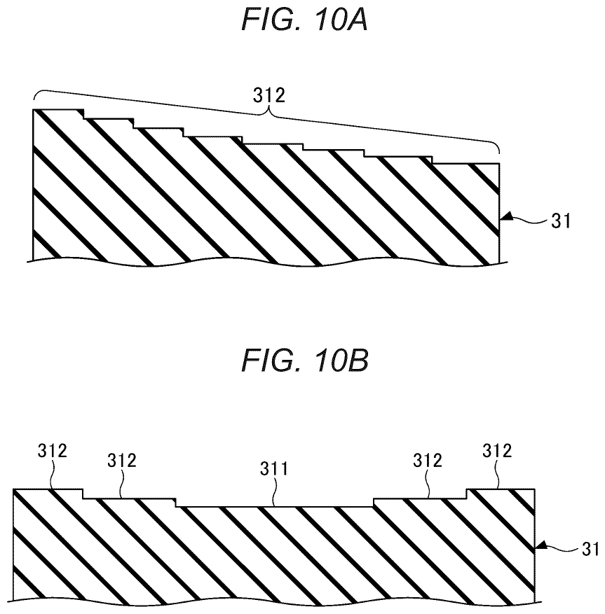

FIGS. 10A and 10B is a partially enlarged cross-sectional view of the substrate fixing device according to variation 1 of the first embodiment, in which FIG. 10A is an enlarged view of part C of FIG. 9B and FIG. 10B is an enlarged view of part D of FIG. 9B. Note that the magnifications of FIGS. 10A and 10B are the same. As shown in FIGS. 9A, 9B, 10A and 10B, the placement surface 31a may, in plan view, have a circular region 311 located at the center and a plurality of annular regions 312 located at the outer periphery of the circular region 311.

In the example of FIG. 9A, the placement surface 31a has 13 annular regions 312. As shown in FIG. 9A, in plan view, an outer edge of each circular region 312 can be arranged concentrically with respect to the center of the circular region 311, for example. In addition, as shown in FIGS. 10A and 10B, the circular region 311 and each annular region 312 may have a stepped shape in which a height of each step increases toward the outer periphery in a cross-sectional view.

When the annular regions 312 have a stepped shape, an upper surface of each annular region 312 may be parallel to the upper surface of the base plate 10 or may be inclined with respect to the upper surface of the base plate 10. In addition, the upper surface of each annular region 312 may be a flat surface, a curved surface, or a combination of flat and curved surfaces.

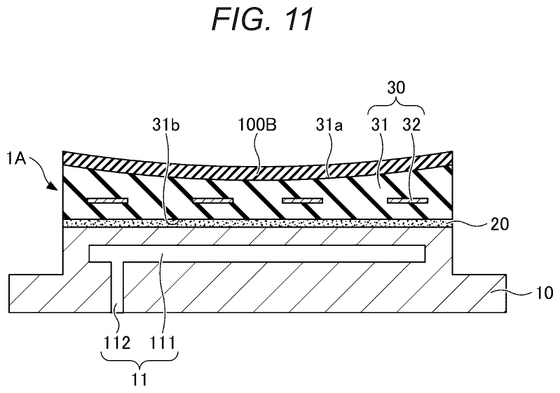

FIG. 11 is a simplified cross-sectional view illustrating a state in which the substrate fixing device according to variation 1 of the first embodiment adsorbs and holds a sapphire substrate. In FIG. 11, a sapphire substrate 100B is warped into a concave shape. The degree of warpage varies depending on the diameter, thickness, manufacturing lot, and the like of the sapphire substrate, but for example, in a sapphire substrate with a diameter of 6 inches and a thickness of 1.5 mm, the warpage may be about 130 μm. That is, in some cases, a difference in height between the center and the outermost periphery may be approximately 130 μm.

When the diameter, thickness, and manufacturing lot of the sapphire substrate 100B to be adsorbed are determined, the tendency of warpage can be determined by extracting samples and measuring the warpage. When the tendency of warpage is determined, the placement surface 31a can be processed to match it, thereby increasing a contact area between the placement surface 31a and the sapphire substrate 100B, as shown in FIG. 11, and enabling favorable adsorption.

To form the placement surface 31a into a concave shape, a mask is arranged on the flat placement surface 31a, similar to FIGS. 7A and 7B of the first embodiment. Thereafter, unlike the first embodiment, first, the innermost periphery region of the mask 200, divided by the slit 200x, is peeled off, and blast processing is performed from the center. Then, the processes of peeling off the region outside the smallest-diameter slit 200x at that point in time and performing blast processing through the mask are repeated until the slit is no longer present. Finally, the mask remaining at the outermost periphery of the placement surface 31a is peeled off.

Thereby, the placement surface 31a has, in plan view, the circular region 311 located at the center and the plurality of annular regions 312 located at the outer periphery of the circular region 311, and in plan view, the outer edge of each of the annular regions 312 is arranged concentrically with respect to the center of the circular region 311. In addition, the circular region 311 and each of the annular regions 312 have a stepped shape in which the height is lowest at the center and increases toward the outer periphery in a cross-sectional view, resulting in a concave shape as a whole. In plan view, the radius of the circular region 311 may be greater than the width of each annular region 312. In addition, the plurality of annular regions 312 may include annular regions 312 with different widths, and the annular region 312 with a greater width may be arranged closer to the circular region 311 than the annular region 312 with a smaller width.

Note that after completely peeling off the mask 200, polishing using a hand stone or the like may be performed on the edges of each step, thereby forming the entire placement surface 31a into a smooth concave shape. Alternatively, the polishing may be performed partially on the edges of each step, thereby forming the placement surface 31a with curved or chamfered edges of each step.

As such, the sapphire substrate may be warped into a convex shape or a concave shape. Therefore, the tendency of warpage of the sapphire substrate is identified in advance, and the placement surface 31a is processed into a convex or concave shape according to the warpage shape. Thereby, it is possible to implement the electrostatic chuck 30 having a simple structure and improved adsorption performance for a target object to be adsorbed having high insulating properties. The electrostatic chuck 30 also exhibits the same effect on a target object to be adsorbed having high insulating properties other than the sapphire substrate.

Note that the simple structure refers to a structure in which, for example, a driving means for displacing an electrostatic chuck body as described in the patent literatures is not required.

Although the preferred embodiments and the like have been described in detail, the present invention is not limited to the above-described embodiments and the like, and a variety of changes and replacements can be made for the above-described embodiments and the like without departing from the scope defined in the claims.

For example, the method of processing the placement surface 31a into a convex or concave shape is not limited to the blast processing. For example, it is possible to process the placement surface into a convex or concave shape using a transverse rotary grinder, a vertical rotary grinder, a machining center, a milling machine, a laser, an electrical discharge machine, or the like.

What is claimed is:

1. An electrostatic chuck comprising:
a base body having a placement surface on which a target object to be adsorbed is to be placed; and
an electrostatic electrode embedded in the base body, wherein
the base body has a flat surface opposite to the placement surface, and
the placement surface is convex or concave with respect to the flat surface.

2. The electrostatic chuck according to claim 1, wherein
the placement surface is convex with respect to the flat surface, and
a height of the placement surface from the flat surface is highest at a center and decreases toward an outer periphery.

3. The electrostatic chuck according to claim 1, wherein
the placement surface is concave with respect to the flat surface, and
a height of the placement surface from the flat surface is lowest at a center and increases toward an outer periphery.

4. The electrostatic chuck according to claim 1, wherein
the placement surface has, in plan view, a circular region located at a center and a plurality of annular regions located at an outer periphery of the circular region,
an outer edge of each of the annular regions is arranged concentrically with respect to a center of the circular region, in plan view, and
the circular region and each of the annular regions have a stepped shape in a cross-sectional view.

5. The electrostatic chuck according to claim 4, wherein a radius of the circular region is greater than a width of each of the annular regions, in plan view.

6. The electrostatic chuck according to claim 5, wherein
the plurality of annular regions comprise the annular regions with different widths, and
the annular region with a greater width is arranged at a position closer to the circular region than the annular region with a smaller width.

7. A substrate fixing device, comprising:
a base plate; and
the electrostatic chuck according to claim 1 provided on the base plate.
